(19) United States
(12) Patent Application Publication
(10) Pub. No.: US 2025/0349916 A1
(43) Pub. Date: Nov. 13, 2025

(54) DEVICE FOR INSPECTING BATTERY CELL POUCH AND OPERATING METHOD USING THE SAME

(71) Applicant: SK On Co., Ltd., Seoul (KR)

(72) Inventor: Chang Gyu JANG, Daejeon (KR)

(21) Appl. No.: 19/002,717

(22) Filed: Dec. 27, 2024

(30) Foreign Application Priority Data
May 10, 2024 (KR) 10-2024-0061788

(51) Int. Cl. H01M 10/42; G01N 25/72; G01R 31/385; G01R 31/389; H01M 50/105

(52) U.S. Cl. CPC H01M 10/4285; G01N 25/72; G01R 31/3865; G01R 31/389; H01M 50/105

(57) ABSTRACT

A battery cell pouch inspection device of the present disclosure includes: an inspection portion measuring insulation resistance of a battery cell pouch using a probe; a thermal detection portion photographing one surface of the battery cell pouch to generate a thermographic image according to temperature distribution; and a control portion analyzing an insulation resistance signal measured by the inspection portion and the thermographic image to determine whether the battery cell pouch is defective.

### CROSS-REFERENCE TO RELATED PATENT APPLICATION

The present application claims priority under 35 U.S.C. § 119(a) to Korean patent application number 10-2024-0061788 filed on May 10, 2024, the entire disclosure of which is incorporated by reference herein.

### BACKGROUND OF THE INVENTION

### 1. Field

The present disclosure relates to a battery cell pouch inspection device and an operating method thereof.

### 2. Description of the Related Art

Recently, demand for mobile devices such as smartphones, tablet PCs, and wireless earphones is increasing. In addition, as the development of electric vehicles, batteries for energy storage, robots, and satellites is carried out in a full scale, research is being actively conducted on high-performance secondary batteries that can be repeatedly charged and discharged, as an energy source.

Secondary batteries are rechargeable batteries that may be produced in a small size with a large capacity, and may be classified into can-type or pouch-type secondary batteries depending on the shape of the external case. A pouch-type secondary battery consists of a battery cell in which electrode tabs are formed on one side of a plate, and a pouch that surrounds and seals the plate so that the electrode tabs may be pulled outward. A battery cell has a plurality of cathode plates and anode plates with a separator interposed therebetween, and the battery cell is embedded in a pouch and sealed, and electrode tabs on one side of the battery cell are pulled outward from the pouch. Such a battery cell embedded in a pouch is referred to as a pouch-type secondary battery.

A pouch-type secondary battery is manufactured by forming a cup portion on a pouch film made of a flexible material. A cup portion with a space for accommodating an electrode assembly is formed on a pouch film, and then the electrode assembly is accommodated in the accommodating space of the cup portion and then sealing and forming are performed to manufacture a pouch-type secondary battery.

### SUMMARY OF THE INVENTION

An object of the present disclosure is to provide a battery cell pouch inspection device capable of determining whether a battery cell pouch is defective by considering the insulation resistance and heat generation properties of the battery cell pouch, and an operating method thereof.

A battery cell pouch inspection device according to one embodiment of the present invention may include: an inspection portion measuring insulation resistance of a battery cell pouch using a probe; a thermal detection portion photographing one surface of the battery cell pouch to generate a thermographic image according to temperature distribution; and a control portion analyzing an insulation resistance signal measured by the inspection portion and the thermographic image to determine whether the battery cell pouch is defective.

In one embodiment of the present invention, the control portion may determine that the battery cell pouch is normal when the insulation resistance signal is within the range of a reference insulation resistance signal.

In one embodiment of the present invention, the control portion may determine the battery cell pouch to be in a primary defective state when the insulation resistance signal is out of the range of a reference insulation resistance signal, and decide a final defective state by analyzing the thermographic image of the battery cell pouch determined to be a primary defective state.

In one embodiment of the present invention, the control portion may analyze color distribution of the thermographic image of the battery cell pouch determined to be in the primary defective state, and decide the battery cell pouch to be in a true defective state when at least some area has a value higher than or equal to a preset temperature.

In one embodiment of the present invention, the control portion may analyze color distribution of the thermographic image of the battery cell pouch determined to be in the primary defective state, and decide the battery cell pouch to be in a false defective state when at least some area has a value lower than a preset temperature

In one embodiment of the present invention, the control portion may determine an area corresponding to a battery cell pouch based on a preset pattern included in the thermographic image.

In one embodiment of the present invention, the control portion may analyze color distribution of the thermographic image to determine whether there is deterioration in each area of the battery cell pouch identified by the pattern.

In one embodiment of the present invention, the inspection portion may apply a inspection voltage to the insulation resistance through a probe to measure the insulation resistance.

An operating method of a battery cell pouch inspection device according to one embodiment of the present invention may include: a step of applying a inspection voltage to one surface of a battery cell pouch using a probe; a step of measuring insulation resistance of the battery cell pouch; a step of primarily determining whether an insulation resistance signal is present within the range of a reference insulation resistance signal; a step of primarily determining the battery cell pouch to be in a primary defective state when the insulation resistance signal is out of the range of the reference insulation resistance signal; and a step of deciding a final defective state by analyzing a thermographic image of the battery cell pouch determined to be in a primary defective state.

In one embodiment of the present invention, in the step of primarily determining, the battery cell pouch may be determined to be normal, when the insulation resistance signal is present within the range of the reference insulation resistance signal.

In one embodiment of the present invention, in the step of deciding a final defective state, the battery cell pouch may be decided to be in a true defective state, when the color distribution of the thermographic image of the battery cell pouch determined to be in a primary defective state is analyzed and at least some area has a value higher than or equal to a preset temperature.

In one embodiment of the present invention, in the step of deciding a final defective state, the battery cell pouch may be decided to be in a true defective state, when the color distribution of the thermographic image of the battery cell pouch determined to be in a primary defective state is analyzed and at least some area has a value lower than a preset temperature.

In one embodiment of the present invention,

According to the present disclosure, a true defect and a false defect of a battery cell pouch can be accurately determined by analyzing insulation resistance and heat generation properties.

### BRIEF DESCRIPTION OF THE DRAWINGS

FIG. 1 shows a diagram for explaining a battery cell pouch inspection device according to one embodiment of the present disclosure.

FIG. 2 shows a diagram for explaining an operating method of a battery cell pouch inspection device according to one embodiment of the present disclosure.

FIG. 3 shows a diagram for explaining an operating method of a battery cell pouch inspection device according to another embodiment of the present disclosure.

FIG. 4 shows a diagram for explaining an operating method of a battery cell pouch inspection device according to still another embodiment of the present disclosure.

FIG. 5 shows a flowchart for explaining an operating method of a battery cell pouch inspection device according to one embodiment of the present disclosure.

### DETAILED DESCRIPTION

The advantages and features of the present disclosure and the methods for achieving them will become clearer with reference to the embodiments described below in detail together with the accompanying drawings. However, the present disclosure is not limited to the embodiments disclosed below, but may be implemented in various different forms, and these embodiments are provided only to make the present disclosure completely and to fully inform the scope of the present disclosure to those skilled in the art to which the present disclosure pertains, and the present disclosure is defined only by the scope of the claims.

The terminology used herein is for the purpose of describing embodiments and is not intended to limit the present disclosure. In this specification, the singular also includes the plural unless specifically stated in the phrase. The terms “comprises” and/or “comprising” as used herein do not preclude the presence or addition of one or more other components in addition to the mentioned components. The same reference numerals refer to the same components throughout the specification, and “and/or” includes each and every combination of one or more of the mentioned components. Although the terms “first,” “second,” and the like are used to describe various components, it is to be understood that these components are not limited by these terms. These terms are merely used to distinguish one component from another. Accordingly, it is to be understood that a first component referred to below may also be a second component within the technical spirit of the present disclosure.

Unless otherwise defined, all terms (including technical and scientific terms) used herein have the same meaning as commonly understood by one of ordinary skill in the art to which the present invention pertains. In addition, terms defined in generally used dictionaries are not to be interpreted ideally or excessively unless explicitly and specifically defined otherwise.

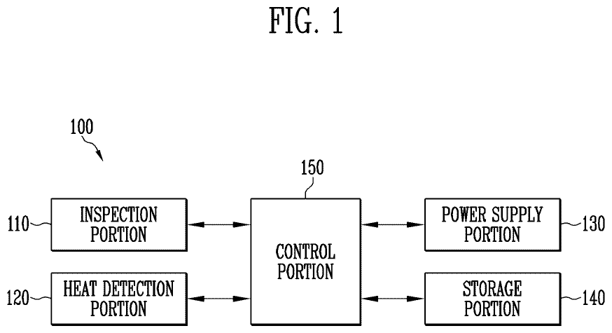

FIG. 1 shows a diagram for explaining a battery cell pouch inspection device according to one embodiment of the present disclosure.

Referring to FIG. 1, the battery cell pouch inspection device 100 may include an inspection portion 110, a heat detection portion 120, a power supply portion 130, a storage portion 140, and a control portion 150.

An inspection portion 110 may measure insulation resistance of a battery cell pouch using a probe. An inspection portion 110 may apply a inspection voltage to one surface of a battery cell pouch by bringing a probe into contact to measure insulation resistance.

In one embodiment, a contact surface of a probe may be any one of a V shape, a U shape, a diagonal shape, a clamp shape, a twisted shape, a hexagonal shape, and an oval shape.

In one embodiment, an inspection portion 110 may apply a inspection voltage increased by a preset unit to a battery cell pouch according to the control by a control portion 150, when it is determined that the battery cell pouch is deteriorated. For example, an inspection portion 110 may apply a inspection voltage of 1 V during initial inspection. Thereafter, when the control portion 150 determines that deterioration has occurred in the battery cell pouch, an inspection voltage at 2 V, 3 V, and 4 V in increments of 1 V may be sequentially applied for more precise determination.

All objects emit infrared rays corresponding to their temperature, and the heat detection portion 120 may measure the infrared rays emitted by an object to calculate the temperature in a non-contact manner. A heat detection portion 120 may photograph a battery cell pouch and generate a thermographic image according to the temperature distribution. For example, a heat detection portion 120 may include an infrared camera or an ultraviolet-infrared camera.

When an inspection voltage is applied to an insulation resistance and heat is generated from the insulation resistance, a heat detection portion 120 may acquire an electromagnetic wave in the infrared region emitted from a battery cell pouch as a thermographic image. For example, a heat detection portion 120 may include various types of detectors, such as a bandgap type cooling detector, a non-cooling microbolometer detector, and an indium antimonide (InSb) detector.

In one embodiment, a heat detection portion 120 may be provided with a magnifying lens that magnifies the magnification and displays an image as an enlarged image. A heat detection portion 120 may improve the detection and identification capabilities by using the magnifying lens in an area having a value higher than a preset temperature.

In another embodiment, a heat detection portion 120 may generate a thermographic image by using at least one of a wave plate, a filter, and a polarizing plate to amplify a signal by reflection of an electromagnetic wave. For example, when it is determined that some area of a thermographic image has a value similar to a preset temperature, a heat detection portion 120 may generate a thermographic image by using at least one of a wave plate, a filter, and a polarizing plate for more accurate determination.

The power supply portion 130 may provide power required for driving each component of a battery cell pouch inspection device 100. A power supply portion 130 may provide an inspection voltage for measuring insulation resistance to an inspection portion 110. A power supply portion 130 may provide an inspection voltage increased by a preset unit according to a request from an inspection portion 110. A storage portion 140 may store a thermographic image generated by a heat detection portion 120. For example, a storage portion 140 may be implemented as a nonvolatile memory such as a flash memory or a volatile memory such as a dynamic random access memory (DRAM), but is not limited thereto.

A control portion 150 may control overall operation of each component of a battery cell inspection device. A control portion 150 may be configured to include a central processing unit (CPU), a micro processor unit (MPU), a micro controller unit (MCU), a graphics processing unit (GPU), or any form of processor well known in the art of the present disclosure.

A control portion 150 may further include a RAM and a read-only memory (ROM) that temporarily and/or permanently store internally processed signals (or data). In addition, a control portion 150 may be implemented in the form of a system-on-chip (SoC) including at least one of a GPU, a RAM, and a ROM.

A control portion 150 may determine whether a battery cell pouch is defective by analyzing an insulation resistance signal measured by an inspection portion 110 and a thermographic image generated by a heat detection portion 120.

A control portion 150 may determine that the battery cell pouch is normal when a insulation resistance signal is present within the range of a reference insulation resistance signal. In one embodiment, the range of an insulation resistance signal may be set differently depending on the capacity, size, thickness, shape, and the like of a battery cell pouch. For example, the range of a reference insulation resistance signal of a battery cell pouch may be set to 100 MΩ to 102 MΩ.

A control portion 150 may determine that the battery cell pouch is in a primary defective state when an insulation resistance signal is out of the range of a reference insulation resistance signal, and decide a final defective state by analyzing a thermographic image of the battery cell pouch determined to be in a primary defective state.

A thermographic image acquired by a heat detection portion 120 may exhibit a specific pattern depending on a temperature distribution state. In particular, a thermographic image is a temporal and spatial image of radiated far-infrared rays, and a control portion 150 may determine not only temperature distribution of a battery cell pouch, but also poor contact between components, poor insulation resistance, internal damage, and the like by analyzing a thermographic image. In other words, when heat is generated from an insulation resistance of a battery cell pouch, a specific thermographic pattern may be exhibited depending on the presence of a defect.

A control portion 150 may determine the temperature of a battery cell pouch in response to the color of a thermographic image. A control portion 150 may determine an area corresponding to a battery cell pouch based on a preset pattern included in a thermographic image. In addition, the control portion 150 may decide the temperature of the battery cell pouch corresponding to the area based on the determined temperature of the thermographic image.

A control portion 150 may determine whether a battery cell pouch is defective by analyzing a thermographic pattern and temperature distribution of a thermographic image.

A control portion 150 may decide that a battery cell pouch is in a true defective state when at least some area of a thermographic image has a value higher than or equal to a preset temperature. In other words, a control portion 150 may determine that abnormal heat generation occurs due to a defect in at least some area of a battery cell pouch.

In contrast, a control portion 150 may decide that a battery cell pouch is in a false defective state when the entire area of a thermographic image has a value lower than a preset temperature. Accordingly, battery cell pouches that have been determined to be in a primary defective state may be determined to be in a false defective state and thus may be used as normal products.

In one embodiment, a control portion 150 may divide a thermographic image into a plurality of image areas according to preset conditions, and may match each of the divided image areas with a battery cell pouch disposed in the corresponding area. In addition, a control portion 150 may select an area in which deterioration has occurred in a thermographic image and may determine that a defect has occurred in the specific area of a battery cell pouch.

In another embodiment, when a plurality of colors are mixed and displayed in a specific area of a thermographic image, a control portion 150 may decide an average of the highest temperature and the lowest temperature among the colors included in the specific area as the temperature of the area.

In another embodiment, when a plurality of colors are mixed and displayed in a specific area of a thermographic image, a control portion 150 may determine the temperature of the color included in the highest proportion within the specific area as the temperature of the area.

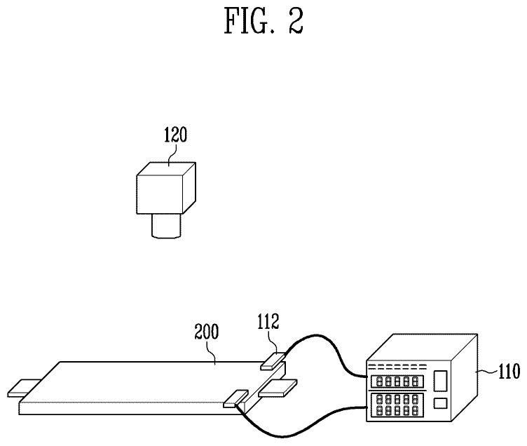

FIG. 2 shows a diagram for explaining an operating method of a battery cell pouch inspection device according to one embodiment of the present disclosure.

Referring to FIG. 2, a battery cell pouch 200 may be a secondary battery that may be reused through charging even after being discharged. For example, a battery cell pouch 200 may be a lithium ion battery cell pouch. A battery cell pouch 200 may include a plurality of electrode layers and a separator disposed between the plurality of electrode layers. A plurality of electrode layers may include at least one anode layer and at least one cathode layer.

A battery cell pouch 200 may be configured in the form of an aluminum film to protect a battery cell. For example, an aluminum film may be used in a form coated with an insulating material such as a polyethylene terephthalate (PET) resin or a nylon resin.

When an upper pouch and a lower pouch are used in a form in which they are joined, casted polypropylene (CPP) or polypropylene (PP) may be used for mutual adhesion, and a sealing surface, which is the outer circumferential surface where the pouches are joined, has a structure of an insulating layer, an aluminum film layer, and an adhesive layer.

When an inspection voltage is applied to an insulation resistance in a normal state, a battery cell pouch 200 may be maintained at a temperature below a preset level. On the other hand, when the internal structure of a battery cell pouch 200 is damaged, a normal-state voltage may not be maintained. In addition, a battery cell pouch 200 with damaged insulation may cause a low voltage and may cause swelling of a battery cell therein. In such a case, a current may be formed at an defective area, and heat may be generated.

During insulation resistance inspection, an inspection portion 110 bring a probe 112 into contact with one surface of a battery cell pouch 200. To prevent poor contact with the battery cell pouch 200, the contact surface of the probe 112 may be provided in any one of a V shape, a U shape, a diagonal shape, a clamp shape, a twisted shape, a hexagonal shape, and an oval shape.

An inspection portion 110 may measure a maximum resistance of an insulation resistance by inputting an AC or DC voltage for a preset time. For example, an inspection portion 110 may measure a maximum resistance for about 1 second by applying an AC of 50 V. An inspection portion 110 may generate an insulation resistance signal and provide it to a control portion 150.

A control portion 150 may analyze an insulation resistance signal measured by an inspection portion 110 to determine whether a battery cell pouch 200 is defective.

A control portion 150 may determine that a battery cell pouch 200 is normal when an insulation resistance signal is present within the range of a reference insulation resistance signal. For example, when the range of a reference insulation resistance signal is 100 MΩ to 102 MΩ and an insulation resistance signal is measured as 101 MΩ, a control portion 150 may determine that a battery cell pouch 200 is in a normal state.

On the other hand, a control portion 150 may determines that a battery cell pouch 200 is in a primary defective state when an insulation resistance signal is out of the range of a reference insulation resistance signal. A control portion 150 may control a heat detection portion 120 to photograph a thermographic image of a battery cell pouch 200 for precise inspection.

A heat detection portion 120 may be fixed to one side of a battery cell inspection device in a form facing a battery cell pouch 200, and may photograph one surface of the battery cell pouch 200 to generate a thermographic image. A heat detection portion 120 may provide a thermographic image photographed for a preset time to a control portion 150. During the period when a heat detection portion 120 photographs a thermographic image, an inspection portion 110 may apply an inspection voltage to a battery cell pouch 200 through a probe 112.

Meanwhile, in this embodiment, a heat detection portion 120 is illustrated as photographing a thermographic image in a direction perpendicular to a battery cell pouch 200. However, the present invention is not limited thereto, and a heat detection portion 120 may be disposed on the side of a battery cell pouch 200 or under a battery cell pouch to generate a thermographic image of the battery cell pouch 200. At this time, a separate distance detection sensor may be used to maintain a certain distance between the heat detection portion 120 and the battery cell pouch 200.

A control portion 150 may determine the temperature of a battery cell pouch 200 in response to the color of a thermographic image. A control portion 150 may determine an area corresponding to a battery cell pouch 200 based on a preset pattern included in a thermographic image. In addition, the control portion 150 may decide the temperature of the battery cell pouch 200 corresponding to the area based on the determined temperature of the thermographic image.

A control portion 150 may decide whether a battery cell pouch 200 is in a final defective state by analyzing temperature distribution of a thermographic image generated by a heat detection portion 120. A control portion 150 may decide that a battery cell pouch 200 is in a true defective state when at least some area of the battery cell pouch 200 has a value higher than or equal to a preset temperature. In other words, a control portion 150 may determine that abnormal heat generation occurs due to a defect in at least some area of a battery cell pouch 200.

In contrast, a control portion 150 may decide that a battery cell pouch 200 is in a false defective state when the entire area of a battery cell pouch 200 has a value lower than a preset temperature. Accordingly, even when a insulation resistance signal is out of the range of a reference insulation resistance, a control portion 150 decide that a battery cell pouch 200 is in a normal state.

In one embodiment, a control portion 150 may determine poor contact between components, poor insulation resistance, internal damage, and the like of a battery cell pouch 200 by analyzing a specific pattern according to a temperature distribution state of a thermographic image. A control portion 150 may divide a thermographic image into a plurality of image areas according to preset conditions, and match each of the divided image areas with a battery cell pouch 200 disclosed in the corresponding area. In addition, a control portion 150 may select an area in a thermographic image where deterioration has occurred and determine that a defect has occurred in the specific area of the battery cell pouch 200.

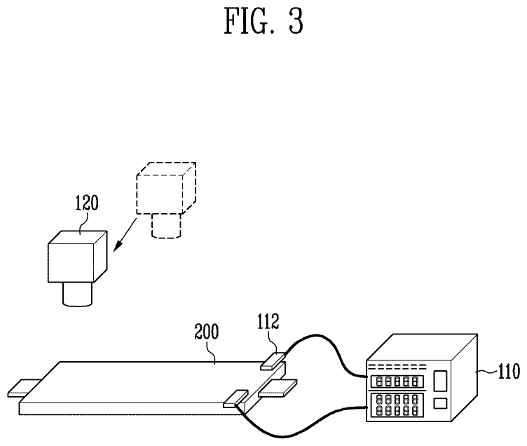

FIG. 3 shows a diagram for explaining an operating method of a battery cell pouch inspection device according to another embodiment of the present disclosure.

Referring to FIG. 3, a control portion 150 may specifically determine the position of a defect by analyzing an enlarged thermographic image of a battery cell pouch 200 that has been determined to be in a true defective state. To this end, the control portion 150 may move a heat detection portion 120 over a defective region of a battery cell pouch 200. The heat detection portion 120 may photograph an enlarged thermographic image on the defective region of the battery cell pouch 200.

A control portion 150 may precisely determine temperature distribution of an enlarged thermographic image to specifically determine the position of the heating of a battery cell pouch 200. As a result, the control portion 150 may determine poor contact between components, poor insulation resistance, internal damage, and the like of the battery cell pouch 200,

In one embodiment, a heat detection portion 120 may generate a thermographic image having an enlarged image through a magnifying lens. A thermographic image may be generated using a magnifying lens without moving a heat detection portion 120 to a defective position. In this case, the heat detection portion 120 may generate a thermographic image using at least one of a wave plate, a filter, and a polarizing plate to correct the resolution of the thermographic image.

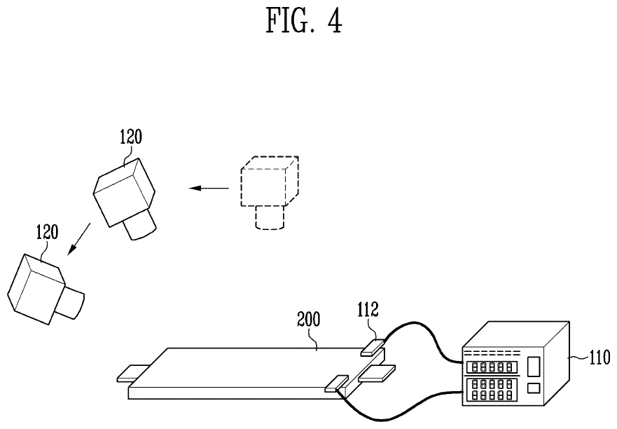

FIG. 4 shows a diagram for explaining an operating method of a battery cell pouch inspection device according to still another embodiment of the present disclosure.

Referring to FIG. 4, a control portion 150 may specifically determine the position of a defect by analyzing thermographic images photographed from various angles of a battery cell pouch 200 that has been determined to be in a true defective state. To this end, the control portion 150 may move the position of a heat detection portion 120 to view the defective region of the battery cell pouch 200 from various angles. The heat detection portion 120 may generate thermographic images of the defective portion of the battery cell pouch 20 photographed from various angles.

A thermographic image photographed on one surface of a battery cell pouch 200 may include temperature distributions of overlapping components. In this case, a control portion 150 may specifically determine the position of the heating of the battery cell pouch 200 by analyzing temperature distribution of each of the thermographic images captured from various angles.

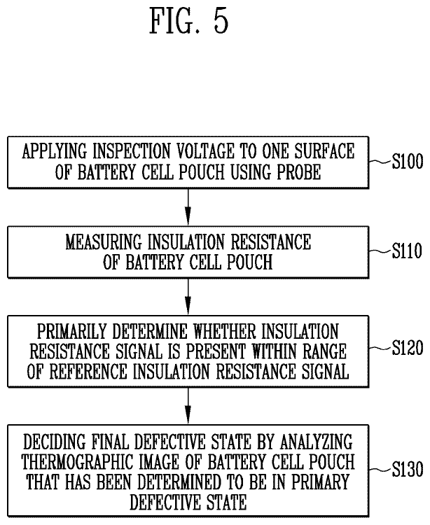

FIG. 5 shows a flowchart for explaining an operating method of a battery cell pouch inspection device according to one embodiment of the present disclosure.

Referring to FIG. 5, a battery cell pouch inspection device 100 may apply an inspection voltage to one surface of a battery cell pouch 200 using a probe 112 to measure insulation resistance (S100).

A battery cell pouch inspection device 100 may measure insulation resistance of a battery cell pouch 200 and generate an insulation resistance signal (S110).

A battery cell pouch inspection device 100 may primarily determine whether an insulation resistance signal is present within the range of a reference insulation resistance signal (S120). A battery cell pouch inspection device 100 may determine that a battery cell pouch 200 is normal when an insulation resistance signal is within the range of a reference insulation resistance signal. On the other hand, a battery cell pouch inspection device 100 may determine that a battery cell pouch 200 is in a primary defective state when an insulation resistance signal is out of the range of a reference insulation resistance signal.

A battery cell pouch inspection device 100 may decide a final defective state by analyzing a thermographic image of a battery cell pouch 200 that has been determined to be in a primary defective state (S130). A battery cell pouch inspection device 100 may decide that a battery cell pouch 200 is in a true defective state when at least some area of a thermographic image has a value higher than or equal to a preset temperature. In contrast, a battery cell pouch inspection device 100 may decide that a battery cell pouch 200 is in a false defective state when the entire area of a thermographic image has a value lower than a preset temperature. Accordingly, battery cell pouches 200 that have been determined to be in a primary defective state may determined to be in a false defective state and thus may be used as normal products.

Although the embodiments of the present disclosure have been described above, it is understood that those skilled in the art to which the present disclosure pertains may make various modifications and implementations without departing from the scope of the claims of the present disclosure.

What is claimed is:

1. A battery cell pouch inspection device comprising:
an inspection portion measuring insulation resistance of a battery cell pouch using a probe;
a thermal detection portion photographing one surface of the battery cell pouch to generate a thermographic image according to temperature distribution; and
a control portion analyzing an insulation resistance signal measured by the inspection portion and the thermographic image to determine whether the battery cell pouch is defective.

2. The battery cell pouch inspection device according to claim 1, wherein the control portion determines that the battery cell pouch is normal when the insulation resistance signal is within the range of a reference insulation resistance signal.

3. The battery cell pouch inspection device according to claim 1, wherein the control portion determines the battery cell pouch to be in a primary defective state when the insulation resistance signal is out of the range of a reference insulation resistance signal, and decides a final defective state by analyzing the thermographic image of the battery cell pouch determined to be a primary defective state.

4. The battery cell pouch inspection device according to claim 3, wherein the control portion analyzes color distribution of the thermographic image of the battery cell pouch determined to be in the primary defective state, and decides the battery cell pouch to be in a true defective state when at least some area has a value higher than or equal to a preset temperature.

5. The battery cell pouch inspection device according to claim 3, wherein the control portion analyzes color distribution of the thermographic image of the battery cell pouch determined to be in the primary defective state, and decides the battery cell pouch to be in a false defective state when at least some area has a value lower than a preset temperature.

6. The battery cell pouch inspection device according to claim 1, wherein the control portion determines an area corresponding to a battery cell pouch based on a preset pattern included in the thermographic image.

7. The battery cell pouch inspection device according to claim 6, wherein the control portion analyzes color distribution of the thermographic image to determine whether there is deterioration in each area of the battery cell pouch divided according to the preset pattern.

8. The battery cell pouch inspection device according to claim 1, wherein the inspection portion applies an inspection voltage to the insulation resistance through a probe to measure the insulation resistance.

9. A operating method of a battery cell pouch inspection device, comprising:
a step of applying a inspection voltage to one surface of a battery cell pouch using a probe;
a step of measuring insulation resistance of the battery cell pouch;
a step of primarily determining whether an insulation resistance signal is present within the range of a reference insulation resistance signal;
a step of primarily determining the battery cell pouch to be in a primary defective state when the insulation resistance signal is out of the range of the reference insulation resistance signal; and
a step of deciding a final defective state by analyzing a thermographic image of the battery cell pouch determined to be in a primary defective state.

10. The operating method of a battery cell pouch inspection device according to claim 9, wherein in the step of primarily determining, the battery cell pouch is determined to be normal, when the insulation resistance signal is present within the range of the reference insulation resistance signal.

11. The operating method of a battery cell pouch inspection device according to claim 9, wherein in the step of deciding a final defective state, the battery cell pouch is decided to be in a true defective state, when the color distribution of the thermographic image of the battery cell pouch determined to be in a primary defective state is analyzed and at least some area has a value higher than or equal to a preset temperature.

12. The operating method of a battery cell pouch inspection device according to claim 9, wherein in the step of deciding a final defective state, the battery cell pouch is decided to be in a true defective state, when the color distribution of the thermographic image of the battery cell pouch determined to be in a primary defective state is analyzed and at least some area has a value lower than a preset temperature.
